(19) United States
(12) Patent Application Publication
(10) Pub. No.: US 2009/0168324 A1
(43) Pub. Date: Jul. 2, 2009

(54) DATA STORAGE SYSTEM WITH HEAT DISSIPATING MODULE

(75) Inventors: Hsiu-Chang Lai, Tu-Cheng (TW); Zhen-Xing Ye, Shenzhen (CN); Xiao-Zhu Chen, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/047,312

(22) Filed: Mar. 12, 2008

(30) Foreign Application Priority Data
Dec. 29, 2007 (CN) 200710203566.4

(51) Int. Cl. H05K 7/20

(52) U.S. Cl. 361/679.33; 361/679.48

(57) ABSTRACT

A data storage system includes a data storage device, a control panel, and a heat dissipating module. The data storage device includes a cage and a plurality of disk drives, wherein the disk drives are accommodated in the cage. The control panel includes a plurality of ventilation holes and a control circuit. The control panel is located at a side of the cage. The control panel is connected to the dissipating module. The control circuit of the control panel is configured to sense the temperature of the data storage device and control power to the heat dissipating module accordingly to dissipate heat of the disk drives.

### BACKGROUND OF THE INVENTION

1. Field of the Invention

The present invention relates to a data storage system with a module for dissipating heat.

2. Description of Related Art

During operation of a computer, heat is generated by the electrical components thereof, especially by electronic packages such as data storage systems. High-speed processing by data storage systems result in a correspondingly high amount of heat being generated. Thus, cooling of data storage systems is an important consideration in designing computers. Generally, cooling fans are used to dissipate heat generated by data storage systems.

However, the cooling fans will work at a constant speed regardless of the temperature of the data storage system, which is not energy efficient.

What is needed, therefore, is a data storage system with a module for dissipating heat which can solve the above problem.

### SUMMARY

An exemplary data storage system includes a data storage device, a control panel, and a heat dissipating module. The data storage device includes a cage and a plurality of disk drives, wherein the disk drives are accommodated in the cage. The control panel includes a plurality of ventilation holes and a control circuit. The control panel is located at a side of the cage. The control panel is connected to the dissipating module. The control circuit of the control panel is configured to sense the temperature of the data storage device and control power to the heat dissipating module accordingly to dissipate heat of the disk drives.

Other advantages and novel features will become more apparent from the following detailed description when taken in conjunction with the accompanying drawings, in which:

### BRIEF DESCRIPTION OF THE DRAWINGS

FIG. 1 is an isometric, exploded view of a data storage system with a module for dissipating heat of an embodiment in accordance with the present invention;

FIG. 2 is a block diagram of FIG. 1; and

FIG. 3 is a circuit diagram of FIG. 2.

### DETAILED DESCRIPTION

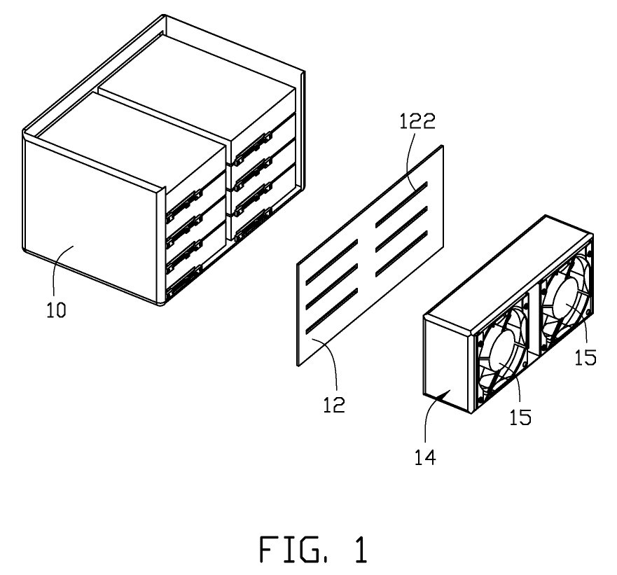

Referring to FIG. 1, a data storage system with a module for dissipating heat in accordance with an embodiment of the present invention includes a data storage device 10, a control panel 12, and a heat dissipating module 14. The data storage device 10 includes a cage and a plurality of disk drives stacked together and accommodated in the cage. The control panel 12, which is located at a side of the cage, includes a plurality of ventilation holes 122 and a control circuit. The control panel 12 is configured to sense the temperature of the data storage device 10, and control the heat dissipating module 14 accordingly to dissipate heat of the disk drives via the ventilation holes 122. The heat dissipating module 14 includes a plurality of cooling fans 15. This embodiment includes two cooling fans 15 as an example. The data storage system is in a computer.

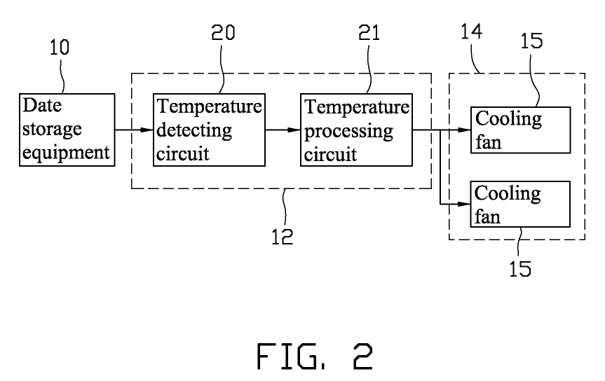

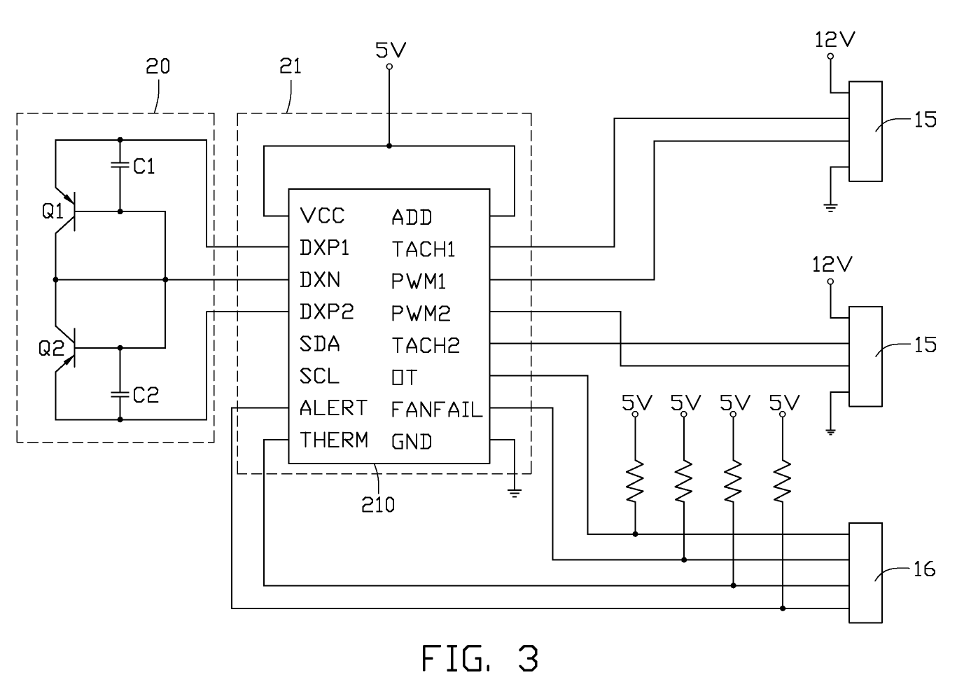

Referring to FIGS. 2 and 3, the control circuit of the control panel 12 includes a temperature detecting circuit 20 and a temperature processing circuit 21. The temperature detecting circuit 20 is configured to sense the temperature of the data storage device 10, and transfer a temperature signal to the temperature processing circuit 21. The temperature processing circuit 21 is configured to control power to the cooling fans 15 according to the temperature signal.

The temperature detecting circuit 20 includes two transistors Q1 and Q2, two capacitors C1 and C2. The collector of the transistor Q1 is connected to the collector of the transistor Q2. The base of the transistor Q1 is connected to the base of the transistor Q2. A node between the collectors of the transistor Q1 and the transistor Q2 is connected to a node between the bases of the transistor Q1 and the transistor Q2. One terminal of the capacitor C1 is connected to the base of the transistor Q1. Another terminal of the capacitor C1 is connected to the emitter of the transistor Q1. One terminal of the capacitor C2 is connected to the base of the transistor Q2. Another terminal of the capacitor C2 is connected to the emitter of the transistor Q2. The transistors Q1 and Q2 are located adjacent the data storage device 10 to sense the temperature of the data storage device 10.

The temperature processing circuit 21 includes a fan controller 210. The fan controller 210 is a MAX6639 fan controller. The fan controller 210 includes three input pins DXP1, DXP2, DXN, two communication pins SCL, SDA, four status pins OT, FANFAIL, ALERT, THERM, four output pins TACH1, TACH2, PWM1 and PWM2. The input pin DXP1 is connected to the emitter of the transistor Q1. The input pin DXP2 is connected to the emitter of the transistor Q2. The input pin DXN is connected to the node between the collectors of the transistors Q1 and Q2. The communication pins SCL, SDA are coupled to other fan controllers to communicate with the other fan controllers. The status pins OT, FANFAIL, ALERT, and THERM are respectively connected to a motherboard of the computer system. The output pins TACH1 and PWM1 are respectively connected to a speed pin and a control pin of one of the cooling fans 15. The output pins TACH2 and PWM2 are respectively connected to a speed pin and a control pin of another cooling fan 15. The four output pins are configured to control the cooling fans 15.

In this embodiment, advantage is taken of the temperature characteristic of a transistor. According to such characteristic, when the transistor has a stable incoming current, the voltage Vbe between the base and the emitter of the transistor will change as ambient temperature changes. When the temperature rises, the voltage Vbe declines. The voltage Vbe of the transistors Q1 and Q2 declines as the temperature of the data storage device 10 increases. As a result, the voltage between the input pin DXN and the input pin DXP1, the input pin DXN and the input pin DXP2 of the fan controller 210 declines. The voltage of the output pins TACH1, PWM1, TACH2, and PWM2 rises. So the rotating speeds of the cooling fans 15 rise.

In other embodiments, the numbers of the cooling fans 15 and the fan controller 210 can be changed according to need.

When the temperature of the data storage device 10 rises, the control circuit of the control panel 12 accelerates rotating speed of the cooling fans 15 to improve heat dissipation. When the temperature of the data storage device 10 declines, the control circuit of the control panel 12 slows the rotating speed of the cooling fans 15 to reduce unnecessary power consumption. Thus, the fan controller 210 can adjust fan speed to be more energy efficient while still providing enough heat dissipation.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternately embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A data storage system comprising:
a data storage device comprising a cage and a plurality of disk drives accommodated in the cage;
a control panel comprising a plurality of ventilation holes and a control circuit, the control panel being located at a side of the cage; and
a heat dissipating module connected to the control panel, wherein the control circuit of the control panel is configured to sense the temperature of the data storage device and control power to the heat dissipating module accordingly to dissipate heat of the disk drives.

2. The data storage system as claimed in claim 1, wherein the control circuit of the control panel comprises a temperature detecting circuit and a temperature processing circuit, the heat dissipating module comprises a first cooling fan, the temperature detecting circuit is configured to sense the temperature of the disk drives, the temperature processing circuit is connected to the temperature detecting circuit and the first cooling fan, the temperature processing circuit is configured to process the temperature and control rotating speed of the first cooling fan accordingly.

3. The data storage system as claimed in claim 2, wherein the temperature detecting circuit comprises a first transistor, the emitter of the first transistor is connected to a first input terminal of the temperature processing circuit, the collector and the base of the first transistor are connected to a second input terminal of the temperature processing circuit.

4. The data storage system as claimed in claim 3, wherein the heat dissipating module further comprises a second cooling fan, the temperature detecting circuit further comprises a second transistor, the emitter of the second transistor is connected to a third input terminal of the temperature processing circuit, the collector of the second transistor is connected to the first transistor, the base of the second transistor is connected to the base of the first transistor, the temperature processing circuit is connected to the second cooling fan.
